(19) United States
(12) Patent Application Publication
(10) Pub. No.: US 2025/0204061 A1
(43) Pub. Date: Jun. 19, 2025

(54) COMPLEMENTARY METAL OXIDE SEMICONDUCTOR IMAGE SENSOR WITH REDUCED P-TYPE REGION WIDTH

(71) Applicant: Applied Materials, Inc., Santa Clara, CA (US)

(72) Inventors: Qintao ZHANG, Mt Kisco, NY (US); Hans-Joachim L. GOSSMANN, Summit, NJ (US); Noriaki MATSUNAGA, Chigasaki (JP); Masato ISHII, Santa Clara, CA (US); Seshadri RAMASWAMI, Saratoga, CA (US); Nikolaos BEKIARIS, Campbell, CA (US); Taichou Papo CHEN, San Jose, CA (US); Zheng YUAN, Saratoga, CA (US)

(73) Assignee: Applied Materials, Inc., Santa Clara, CA (US)

(21) Appl. No.: 18/542,318

(22) Filed: Dec. 15, 2023

(51) Int. Cl. H01L 27/146

(52) U.S. Cl. CPC H10F 39/014; H10F 39/18

(57) ABSTRACT

Approaches herein provide devices, systems, and methods of transistor patterning using a frontside implant plus epitaxial process to form a graded junction having a high surface doping concentration for a vertical contact transistor bitline. One method may include providing a main body of a complementary metal oxide semiconductor image sensor, and forming a plurality of trenches in the main body, each of the plurality of trenches comprising a set of sidewalls and a base extending between the set of sidewalls. The method may further include forming a doped p-type layer along each of the set of sidewalls using at least one of: a plasma doping process, and an epitaxy process, and forming an oxide layer over the doped p-type layer. The method may further include forming a p-type fill over the oxide layer.

### FIELD OF THE DISCLOSURE

The present embodiments relate to image sensors and, more particularly, to forming a complementary metal-oxide-semiconductor image sensor with a reduced p-type region.

### BACKGROUND OF THE DISCLOSURE

Integrated circuits (ICs) with image sensors are used in a wide range of modern-day electronic devices, such as, for example, cameras, cell phones, tablets, etc. In recent years, complementary metal-oxide-semiconductor (CMOS) image sensors have begun to see widespread use, largely replacing charge-coupled device (CCD) image sensors. Compared to CCD image sensors, CMOS image sensors are favored due to low power consumption, small size, fast data processing, a direct output of data, and low manufacturing cost. Some types of CMOS image sensors include frontside illuminated (FSI) image sensors and backside illuminated (BSI) image sensors.

Image sensors include an array of pixels having photosensitive elements (e.g., photodiodes) that absorb a portion of an incident image light and generate image charge upon absorption of the image light. The image charge of each of the pixels may be measured as an output voltage of each photosensitive element that varies as a function of the incident image light. In other words, the amount of image charge generated is proportional to the intensity of the image light, which is utilized to produce a digital image (i.e., image data) representing the external scene.

IC technologies for image sensors are constantly being improved, especially with the constant demand for higher resolution and lower power consumption. Such improvements frequently involve scaling down device geometries to achieve lower fabrication costs, higher device integration density, higher speeds, and better performance. However, as the miniaturization of image sensors progresses, defects within the image sensor architecture become more readily apparent and may reduce the image quality of the image. For example, excess current leakage within certain regions of the image sensor may cause high dark current, sensor noise, white pixel defects, and the like. These defects may significantly deteriorate the image quality from the image sensor, which may result in reduced yield and higher production costs.

Furthermore, in current BSI and Full-Depth Deep Trench Isolation (FDTI) schemes, p-type regions (e.g., boron doped) are relatively wide and thus consume effective photodiode area, resulting in degraded full-well capacity. The wide p-type regions are due to fast boron diffusion and significant thermal budget after implantation. One current approach to address these deficiencies is to reduce p-type implantation dose and increase n-type photodiode (PD) dose. Another approach is to add a high-K layer to recover hole concentration. However, these approaches cannot be adopted in high volume manufacturing (HVM) because reduced p-type implantation dose causes higher dark current and the high-K layer (e.g., HfO) can't sustain high thermal budget.

Accordingly, improved approaches are needed for reducing p-type region of CIS without reducing interface hole concentration.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a main body of a complementary metal oxide semiconductor image sensor, and forming a plurality of trenches in the main body, each of the plurality of trenches comprising a set of sidewalls and a base extending between the set of sidewalls. The method may further include forming a doped p-type layer along each of the set of sidewalls using at least one of: a plasma doping process, and an epitaxy process, and forming an oxide layer over the doped p-type layer. The method may further include forming a p-type fill over the oxide layer.

In another aspect, a method of forming a complementary metal oxide semiconductor image sensor may include providing a photodiode body, and forming a plurality of trenches in the photodiode body, each of the plurality of trenches comprising a set of sidewalls and a base extending between the set of sidewalls. The method may further include forming a doped p-type layer along each of the set of sidewalls and along the base using at least one of: a plasma doping process, and an epitaxy process, forming an oxide layer over the doped p-type layer, and forming a p-type fill over the oxide layer.

In yet another aspect, an apparatus for forming a complementary metal oxide semiconductor image sensor may include an ion processing tool within one or more processing chambers, the ion processing tool operable to form a doped p-type layer along each sidewall of a plurality of trenches formed in a photodiode body, wherein the doped p-type layer is formed using one of: a plasma treatment, and an epitaxy process, wherein an oxide layer is formed over the doped p-type layer, and wherein a p-type fill is formed over the oxide layer.

### BRIEF DESCRIPTION OF THE DRAWINGS

The accompanying drawings illustrate exemplary approaches of the disclosure, including the practical application of the principles thereof, as follows:

FIG. 1 illustrates a side view of a main body of a complementary metal oxide semiconductor image sensor (CIS), including plurality of trenches formed therein, according to embodiments of the present disclosure;

FIG. 2 illustrates a side view of the main body following a wet etch process, according to embodiments of the present disclosure;

FIG. 3 illustrates a side view of the main body following a sacrificial oxide formation, according to embodiments of the present disclosure;

FIG. 4 illustrates the main body following removal of the sacrificial oxide and formation of an epitaxial layer within each of the trenches, according to embodiments of the present disclosure;

FIG. 5 illustrates a doped p-type layer formed within the trenches, over the epitaxial layer, according to embodiments of the present disclosure;

FIG. 6 illustrates formation of an oxide layer over the doped p-type layer, within the trenches, according to embodiments of the present disclosure;

FIG. 7 illustrates formation of a fill material within each of the trenches, according to embodiments of the present disclosure;

FIG. 8 illustrates a side view of a main body of another CIS, including plurality of trenches formed therein, according to embodiments of the present disclosure;

FIG. 9 illustrates a nitridation treatment performed on an oxide layer within the trenches, according to embodiments of the present disclosure;

FIG. 10 illustrates a plasma treatment to form a doped p-type layer within each of the trenches, followed by formation of a fill material over the oxide layer, according to embodiments of the present disclosure;

FIG. 11 illustrates a perspective view of an example plasma doping system, according to embodiments of the present disclosure; and

FIG. 12 illustrates a perspective view of an example processing system, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments of the present disclosure provide an integration solution to reduce p-type region width without degrading interface hole concentration. As will be described herein, plasma doping (PLAD) and/or epitaxy process steps can be used as part of a backside implant process flow to improve full deep trench isolation (FDTI) full well capacity (FWC) without degrading dark current.

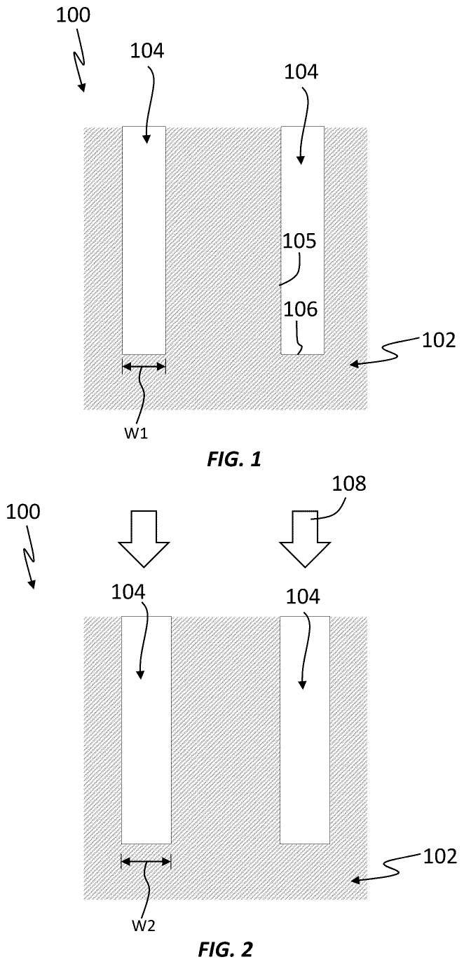

With reference to FIG. 1, an approach for forming a portion of a device 100, which may be a complementary metal oxide semiconductor image sensor (CIS), according to one or more embodiments will be described. The device 100 may include a photodiode (PD) body 102, wherein a plurality of trenches 104 have been formed therein. In some embodiments, a p-type epitaxy may be deposited over a base (not shown) to provide the PD body 102 of a CIS pixel, and an ion implantation may be performed to form a PD deep n-well. The trenches 104 may be formed as part of a deep trench isolation (DTI) dry etch process. The trenches 104 have a set of sidewalls 105 and a base 106, and the trenches 104 may have a width ‘W1’ extending between the sidewalls 105.

As shown in FIG. 2, a wet etch 108 may be performed to recess the sidewalls 105 of the trenches 104. After the wet etch 108, one or more of the trenches 104 may have a width (W2) greater than the width (W1) of the trenches 104 in FIG. 1. In some embodiments, the wet etch 108 may not be necessary in the case W1 is great enough.

As shown in FIG. 3, a sacrificial layer 110 may be formed within the trenches 104. In some embodiments, a decoupled plasma oxidation (DPO) or a remote plasma oxygen (RPO) process may be used to grow a screen oxide within the trenches 104, to a desired thickness (e.g., 5 to 20 nm). Although not shown, the sacrificial layer 110 may also be formed along an upper surface 112 of the body 102, and then removed.

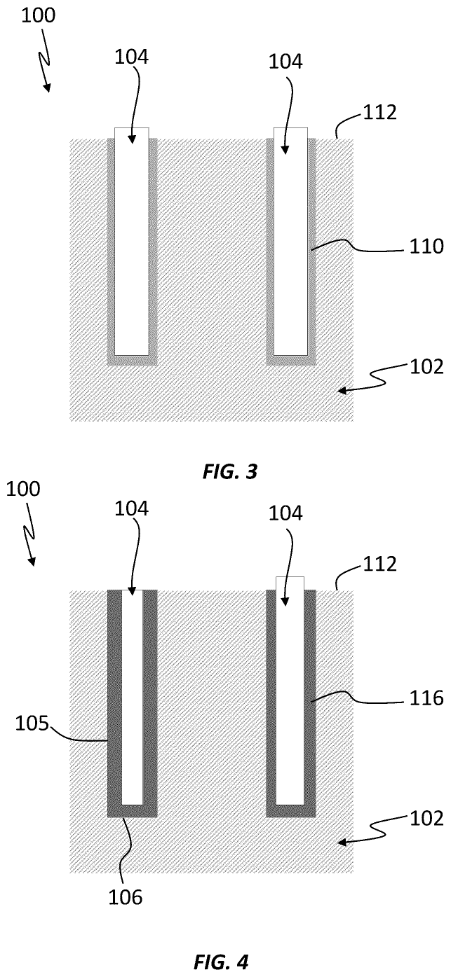

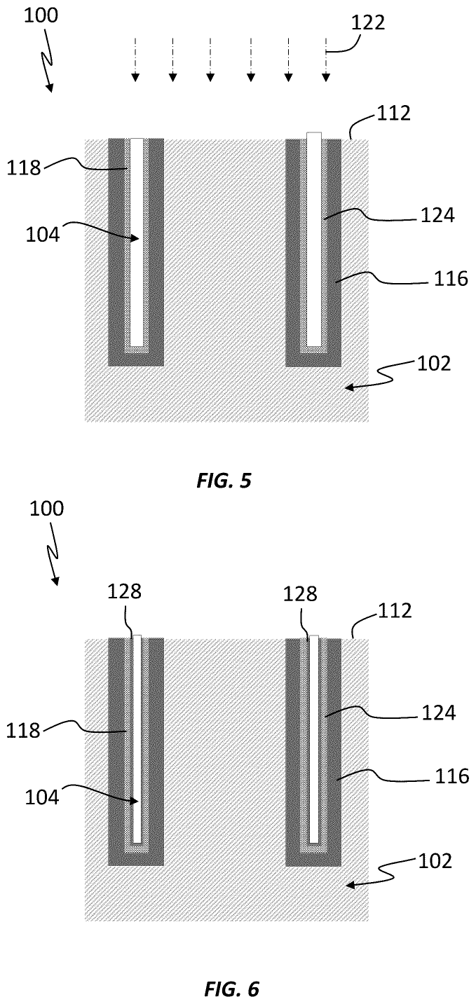

As shown in FIG. 4, the sacrificial layer 110 may be removed, and an epitaxial layer 116 may be formed within each of the trenches 104. In some embodiments, the sacrificial layer 110 may be removed using a wet etch, and the epitaxial layer 116 may be an n-type material (e.g., arsenic doped), which is grown along the sidewalls 105 and the base 106 of the trenches 104. Although not shown, the epitaxial layer 116 may also be formed along the upper surface 112 of the body 102, and then removed.

As shown in FIG. 5, a doped p-type layer 124 may then be formed within the trenches 104, over the epitaxial layer 116. The doped p-type layer 124 may have a desired dopant concentration, e.g., between 10¹⁴ cm⁻³ and 10²¹ cm⁻³, and may be formed using a plasma treatment 122, e.g., plasma doping (PLAD) or decoupled plasma treatment (DPX), which impacts the epitaxial layer 116. In some non-limiting embodiments, this plasma doping is done at a high temperature (e.g., 400° C. or greater) to avoid any potential damage along the sidewalls 105. In other embodiments, the p-type layer 124 may be a thin epitaxial layer, which is grown atop the exposed surfaces of the epitaxial layer 116.

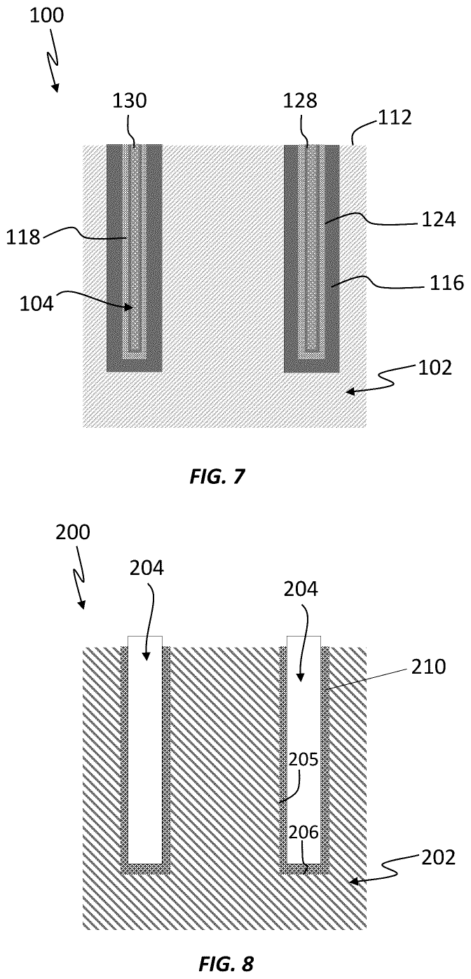

As shown in FIG. 6, an oxide layer 128 may then be formed over the doped p-type layer 124, within the trenches 104. The oxide layer 128 may be a passivation layer. In various embodiments, the oxide layer 128 may be grown or deposited, and then nitridated to form a SiN layer, for example.

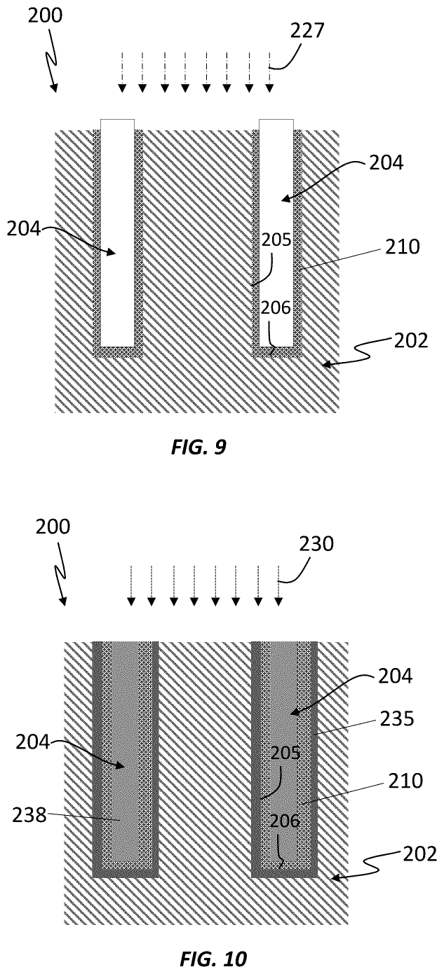

As shown in FIG. 7, a fill material 130 may then be formed within the trenches 104. In some embodiments, the fill material 130 may be a p-type polysilicon, which is deposited in the trenches 104 and then planarized selective to the upper surface 112 of the body 102.

After formation of the fill material 130, one or more front-end-of-the-line (FEOL) processes may be performed. Although not shown, these processes may include shallow trench isolation (STI), well implant, P-pining implant, FD implant, and gate formation, including gate oxide formation, poly gate deposition, etching, etc. One or more back-end-of-the-line (BEOL) processes may also be performed, prior to filter and lens formation.

Turning to FIG. 8, another approach for forming a portion of a device 200 will be described. The device 200 may be a CIS including a photodiode (PD) body 202, wherein a plurality of trenches 204 have been formed into the body 202. In some embodiments, a p-type epitaxy may be deposited over a base (not shown) to provide the PD body 202, and an ion implantation may be performed to form a PD deep n-well. The trenches 204 may be formed as part of a DTI dry etch process.

As further shown, an oxide layer 210 may be formed over the body 202, within the trenches 204. In some embodiments, the oxide layer 210 is grown within the trenches 204 via an RPO process. Although non-limiting, the oxide layer 210 may have an approximate thickness between 5 and 20 nm.

Next, as shown in FIG. 9, a nitridation treatment 227 may be performed, which impacts the oxide layer 210. In some embodiments, the nitridation treatment 227 may be a decoupled plasma nitridation to the oxide layer 210.

As shown in FIG. 10, a plasma treatment 230 may then be performed to form a doped p-type layer 235 within each of the trenches 204, followed by formation of a fill material 238 (e.g., polysilicon) over the oxide layer 210. In some embodiment, prior to formation of the fill material 238, the oxide layer 210 may be further grown to a desired thickness. Using this approach may avoid PLAD's low-dose instability, while nitridation induced higher-K helps better poly to photodiode coupling and, thus, higher concentration of holes.

After formation of the fill material 238, one or more FEOL and BEOL processes may be performed, followed by filter and lens formation.

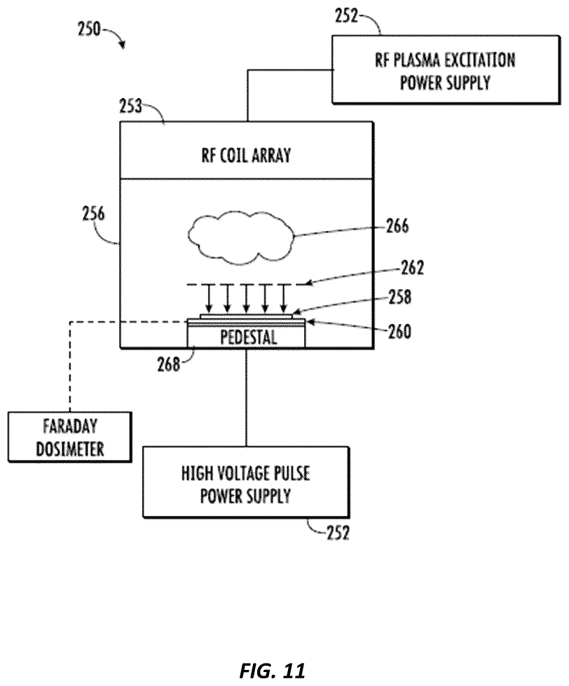

FIG. 11 demonstrates an example, non-limiting PLAD tool or system 250, which provides pulsed RF-excited continuous plasma doping. As shown, the system 250 may include a plasma power supply 251, a voltage pulse power supply 252, an RF coil array 253, and a dosimeter 254. Within a plasma chamber 256 is a wafer/substrate 258. A platen/pedestal 260 may support the wafer 258, and a sheath 262 may be formed above the wafer 258. The dosimeter 254 may be a Faraday dosimeter or other type of sensor that directly measures the dose of ions received by the wafer 258. Although non-limiting, the dosimeter can be located on the pedestal 260, proximate to the wafer 258.

During use, the plasma power supply 252 and the RF coil array 253 deliver radio frequency excitation to generate a plasma 266 when gaseous species are delivered into the plasma chamber 256. For example, the plasma power supply 251 may be an RF powered inductively coupled power source to generate inductively coupled plasma 266, as known in the art. Gaseous species may be delivered from one or more gas sources (not separately shown) to generate radicals and/or ions of any suitable species, such as H₂ and D₂.

The voltage pulse power supply 252 may generate a bias voltage between the wafer 258 and the plasma chamber 256. As such, when the voltage pulse power supply 252 generates a voltage between the plasma chamber 256 and the substrate 258, a similar, but slightly larger, voltage difference is generated between the plasma 266 and the substrate 258. In one non-limiting example, a 5000 (5 kV) voltage difference established between the plasma chamber 256 and the substrate 258 (or, equivalently, pedestal 214) may generate a voltage difference of approximately 5005 V to 5030 V between the plasma 266 and the substrate 258.

In some embodiments, the voltage pulse power supply 252 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 250 may further include a controller (not shown), to control the pulsing routine applied to the substrate 258.

According to various embodiments, the plasma 266 may be formed at least in part of ions that constitute an amorphizing species, wherein the amorphizing species may be any suitable ion capable of amorphizing an initially crystalline region of materials, such as the substrate 258. When the plasma 266 is present in the plasma chamber 256, the controller may generate a signal for the voltage pulse power supply 252 to apply a pulse routine to the substrate 258, where the pulse routine constitutes a plurality of extraction voltage pulses. As such, when the extraction voltage pulses are applied between the substrate 258 and plasma 266, ions are extracted in pulsed form from the plasma 266, generating a plurality of ion pulses that are directed to the substrate 258.

In some embodiments, the platen/pedestal 260 may include an external or internal heating element 268, such as a resistive heater, or may be heated using radiant heat, such as heating lamps disposed above or below the platen/pedestal 260. In other embodiments, the heating element 268 may additionally, or alternatively, be located in a load lock chamber or a separate pre-heat chamber to pre-heat the wafer before it reaches the platen/pedestal 260.

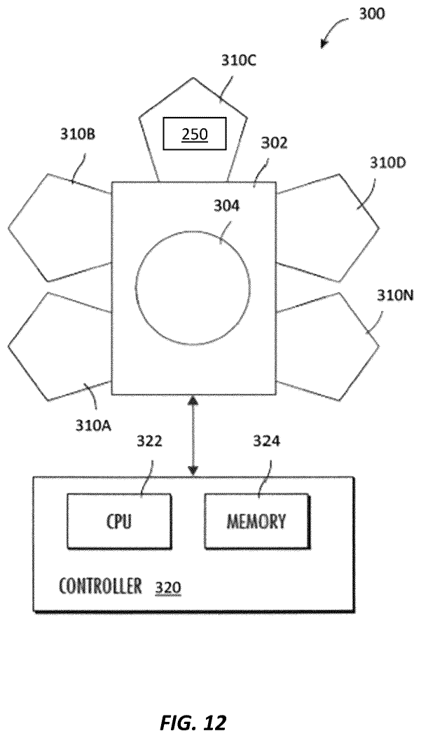

FIG. 12 shows a schematic of another example system/apparatus 300 according to embodiments of the disclosure. In some embodiments, the system 300 may be a cluster tool operable to perform processes necessary to form the device 100 and/or the device 200 described herein. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support ion implantation, material deposition, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be a deposition chamber operable to deposit one or more layers of the devices 100, 200. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition.

In some embodiments, processing chamber 310B may be an etch chamber operable to form trenches through the body of the devices 100, 200. In some embodiments, processing chamber 310B may be used for wet and/or dry etch processes. In some embodiments, the processing chamber 310B may be operable to planarize the devices 100, 200, e.g., to partially remove the fill material.

In some embodiments, processing chamber 310C may be operable to perform a plasma treatment to the devices 100, 200. For example, processing chamber 310C may include PLAD tool or system 250. In some embodiments, the system 250 is operable to form the doped p-type layer along each sidewall of trenches formed in the photodiode body, wherein the oxide layer is formed over the doped p-type layer, and wherein the p-type fill is formed over the oxide layer.

In some embodiments, processing chamber 310D may be operable to perform one or more annealing processes, such as during FEOL and/or BEOL processing.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processor 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
providing a main body of a complementary metal oxide semiconductor image sensor;
forming a plurality of trenches in the main body, each of the plurality of trenches comprising a set of sidewalls and a base extending between the set of sidewalls;
forming a doped p-type layer along each of the set of sidewalls using at least one of: a plasma doping process, and an epitaxy process;
forming an oxide layer over the doped p-type layer; and
forming a p-type fill over the oxide layer.

2. The method of claim 1, further comprising performing a wet etch to increase a width of the plurality of trenches, wherein the oxide layer is formed after the wet etch is performed.

3. The method of claim 1, further comprising:
forming a sacrificial layer along the set of sidewalls after the plurality of trenches are formed in the main body;
removing the sacrificial layer; and
forming an n-type layer along the set of sidewalls after the sacrificial layer is removed, wherein the doped p-type layer is formed along each of the set of sidewalls after the n-type layer is formed.

4. The method of claim 3, wherein forming the sacrificial layer comprises forming an oxide along the set of sidewalls and along the base.

5. The method of claim 1, further comprising performing a nitridation process on the oxide layer.

6. The method of claim 5, wherein the oxide layer is silicon nitride following the nitridation process.

7. The method of claim 1, wherein the oxide layer is formed prior to formation of the doped p-type layer.

8. The method of claim 1, wherein the oxide layer is formed after formation of the doped p-type layer.

9. The method of claim 1, wherein the plurality of trenches are formed in the main body using a dry etch process.

10. The method of claim 1, further comprising performing a planarization process following formation of the p-type fill.

11. A method of forming a complementary metal oxide semiconductor image sensor, the method comprising:
providing a photodiode body;
forming a plurality of trenches in the photodiode body, each of the plurality of trenches comprising a set of sidewalls and a base extending between the set of sidewalls;
forming a doped p-type layer along each of the set of sidewalls and along the base using at least one of: a plasma doping process, and an epitaxy process;
forming an oxide layer over the doped p-type layer; and
forming a p-type fill over the oxide layer.

12. The method of claim 11, further comprising performing a wet etch to increase a width of the plurality of trenches, wherein the oxide layer is formed after the wet etch is performed.

13. The method of claim 11, further comprising:
forming a sacrificial layer along the set of sidewalls after the plurality of trenches are formed in the photodiode body;
removing the sacrificial layer; and
forming an n-type layer along the set of sidewalls after the sacrificial layer is removed, wherein the doped p-type layer is formed along each of the set of sidewalls after the n-type layer is formed.

14. The method of claim 11, further comprising performing a nitridation process on the oxide layer to form silicon nitride.

15. The method of claim 11, wherein the oxide layer is formed prior to formation of the doped p-type layer.

16. The method of claim 11, wherein the oxide layer is formed after formation of the doped p-type layer.

17. The method of claim 11, further comprising:
comprising performing a planarization process following formation of the p-type fill, wherein the p-type fill is removed selective to an upper surface of the photodiode body; and
performing a plurality of front-end-of-line processes after the planarization process.

18. An apparatus for forming a complementary metal oxide semiconductor image sensor, the apparatus comprising an ion processing tool within one or more processing chambers, the ion processing tool operable to form a doped p-type layer along each sidewall of a plurality of trenches formed in a photodiode body, wherein the doped p-type layer is formed using one of: a plasma treatment, and an epitaxy process, wherein an oxide layer is formed over the doped p-type layer, and wherein a p-type fill is formed over the oxide layer.

19. The apparatus of claim 18, wherein the plurality of trenches are formed by the ion processing tool using an ion etch process, wherein a wet etch is performed after the ion etch to increase a width of the plurality of trenches, and wherein the oxide layer is formed after the wet etch is performed.

20. The apparatus of claim 18, wherein the plasma treatment is one of: a plasma doping process, and a decoupled plasma treatment.
